(19) United States
(12) Patent Application Publication
(10) Pub. No.: US 2026/0255974 A1
(43) Pub. Date: Aug. 27, 2026

(54) SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/256,183

(22) Filed: Jul. 1, 2025

(30) Foreign Application Priority Data
Feb. 27, 2025 (KR) 10-2025-0025643

(51) Int. Cl. H01L 23/00; H01L 21/78; H01L 23/544

(52) U.S. Cl. CPC H10W 42/121; H10P 54/00; H10W 46/00; H10W 46/301

(57) ABSTRACT

A semiconductor device according to embodiments of the present disclosure may include a substrate including a chip region and a scribe lane region disposed around the chip region, the scribe lane region including an inner boundary that abuts the chip region and an outer boundary that is spaced apart from the inner boundary; alignment patterns disposed in the scribe lane region on the substrate, spaced apart from each other in a direction in which the outer boundary extends, and disposed spaced apart from the outer boundary; and cutting guide patterns located in the scribe lane region on the substrate, overlapping with at least some of the alignment patterns, and disposed in a direction that intersects the alignment patterns.

### CROSS-REFERENCE TO RELATED APPLICATION

The present application claims priority under 35 U.S.C. § 119(a) to Korean Patent Application No. 10-2025-0025643 filed on Feb. 27, 2025, which is incorporated herein by reference in its entirety.

### BACKGROUND

### 1. Technical Field

Embodiments of the present disclosure relate generally to a semiconductor device and, more particularly, to a semiconductor device comprising a chip region and a scribe lane region disposed around the chip region.

### 2. Related Art

Semiconductor chips are attracting attention as an important element in the electronics industry.

As the electronics industry advances, semiconductor chips are gradually becoming more highly integrated. As semiconductor chips are highly integrated, the size of the chips is gradually decreasing, and the number of semiconductor chips formed on a single wafer is increasing.

Semiconductor chips play a crucial role in the electronics industry, gaining attention for their miniaturization, multi-functionality, and cost-effectiveness. With technological advancements, these chips are becoming more integrated, resulting in smaller chip sizes and an increased number of chips on a single wafer.

In semiconductor manufacturing, a chip region refers to the active area on a wafer where the intricate circuits and components are fabricated to perform specific electronic functions. Surrounding this, the scribe lane region serves as a buffer zone that facilitates the separation of individual chips from the wafer during the cutting (or “dicing”) process. However, as integration levels rise, the cutting process becomes increasingly complex.

### SUMMARY

Embodiments of the present disclosure are directed to providing a semiconductor device in which a cutting defect occurring during a cutting process may be minimized.

Advantages of the embodiments of the disclosure are not limited to those set forth herein, and other unmentioned advantages would be apparent to one of ordinary skill in the art from the following description.

In an embodiment of the present disclosure, a semiconductor device may include a substrate including a chip region and a scribe lane region disposed around the chip region, the scribe lane region including an inner boundary that abuts the chip region and an outer boundary that is spaced apart from the inner boundary; alignment patterns disposed in the scribe lane region on the substrate, spaced apart from each other in a direction in which the outer boundary extends, and disposed spaced apart from the outer boundary; and cutting guide patterns located in the scribe lane region on the substrate, overlapping with at least some of the alignment patterns, and disposed in a direction that intersects the alignment patterns.

In an embodiment of the present disclosure, a semiconductor device may include a substrate including a chip region and a scribe lane region disposed around the chip region; alignment patterns disposed in the scribe lane region on the substrate, and spaced apart from each other in a direction in which a boundary between the chip region and the scribe lane region extends; and cutting guide patterns disposed in the scribe lane region on the substrate, overlapping with at least some of the alignment patterns, and having a width in a direction that intersects the alignment patterns wider than a width in a direction that intersects the boundary between the chip region and the scribe lane region.

According to the embodiments of the present disclosure, it is possible to provide a semiconductor device in which a cutting defect occurring during a cutting process may be minimized.

The advantageous effects of the embodiments of the present disclosure are not limited to the foregoing effects, and other effects will be apparent to one of ordinary skill in the art from the following detailed description.

### BRIEF DESCRIPTION OF THE DRAWINGS

The embodiments of the present disclosure will be more fully understood from the following detailed description and the accompanying drawings, which are provided for illustration only and are not intended to limit the embodiments.

FIG. 1 is a view illustrating a planar structure of a semiconductor device according to embodiments of the present disclosure.

FIG. 2 is an enlarged view of a part 10 of FIG. 1.

FIG. 3 is a view illustrating a cross-sectional structure of a part indicated by a line I-I′ of FIG. 2.

FIG. 4 is a view illustrating a cross-sectional structure of a part indicated by a line II-II′ of FIG. 2.

FIG. 5 is an enlarged view illustrating another embodiment of the part 10 of FIG. 1.

FIG. 6 is a view illustrating a cross-sectional structure of a part indicated by a line III-III′ of FIG. 5.

FIG. 7 is a view illustrating a cross-sectional structure of a part indicated by a line IV-IV′ of FIG. 5.

FIG. 8 is an enlarged view illustrating another embodiment of the part 10 of FIG. 1.

FIG. 9 is a view illustrating a cross-sectional structure of a part indicated by a line V-V′ of FIG. 8.

FIG. 10 is a view illustrating a cross-sectional structure of a part indicated by a line VI-VI′ of FIG. 8.

FIG. 11 is an enlarged view illustrating another embodiment of the part 10 of FIG. 1.

FIG. 12 is a view illustrating a cross-sectional structure of a part indicated by a line VII-VII′ of FIG. 11.

FIG. 13 is an enlarged view illustrating another embodiment of the part 10 of FIG. 1.

FIG. 14 is a view illustrating a cross-sectional structure of a part indicated by a line VIII-VIII′ of FIG. 13.

### DETAILED DESCRIPTION

Embodiments of the present disclosure are described in detail with reference to the accompanying drawings. Specific structural or functional descriptions of the embodiments are provided to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one embodiment, and the second element may be named as a first element in another embodiment.

In the description, when an element included in an embodiment is described in singular form, the element may be interpreted to include a plurality of elements performing the same or similar functions.

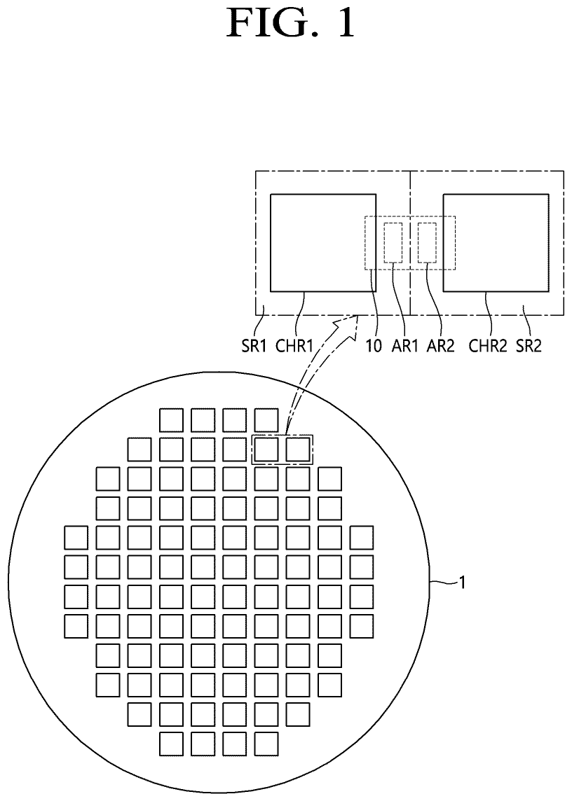

FIG. 1 is a view illustrating a planar structure of a semiconductor device according to embodiments of the present disclosure.

Referring to FIG. 1, a wafer 1 may include a plurality of chip regions and a scribe lane region. Each chip region may refer to a region that forms a semiconductor device. The scribe lane region may refer to a region between the chip regions. In an embodiment, a semiconductor device may include at least a part of the scribe lane region.

The chip regions may include a first chip region CHR1 and a second chip region CHR2. The first chip region CHR1 and the second chip region CHR2 may be regions that are included in different semiconductor devices, respectively. The scribe lane region may include a first scribe lane region SR1 around the first chip region CHR1 and a second scribe lane region SR2 around the second chip region CHR2. The first scribe lane region SR1 and the second scribe lane region SR2 may be included in different semiconductor devices, respectively.

A first alignment pattern region AR1 is disposed in the first scribe lane region SR1. A second alignment pattern region AR2 is disposed in the second scribe lane region SR2. The first alignment pattern region AR1 and the second alignment pattern region AR2 may be regions where various keys used to align components included in semiconductor devices when forming the semiconductor devices are disposed.

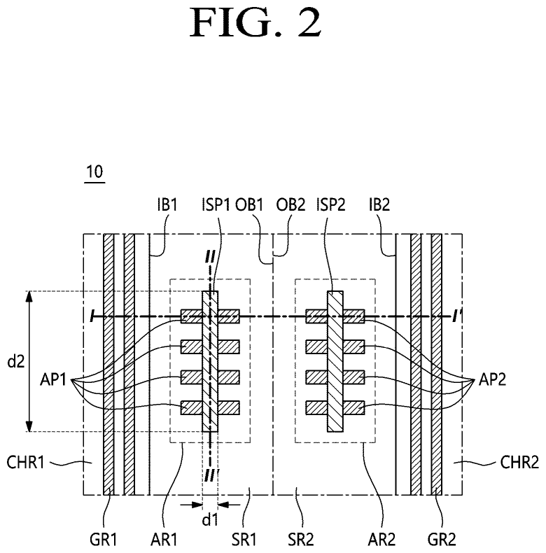

FIG. 2 is an enlarged view of a part 10 of FIG. 1.

Hereinafter, for the sake of convenience, a semiconductor device including the first chip region CHR1 and the first scribe lane region SR1 will be referred to as a first semiconductor device, and a semiconductor device including the second chip region CHR2 and the second scribe lane region SR2 will be referred to as a second semiconductor device.

The first scribe lane region SR1 may include a first inner boundary IB1 that abuts the first chip region CHR1 and a first outer boundary OB1 that is spaced apart from the first inner boundary IB1. The second scribe lane region SR2 may include a second inner boundary IB2 that abuts the second chip region CHR2 and a second outer boundary OB2 that is spaced apart from the second inner boundary IB2. The first inner boundary IB1 may mean the boundary between the first chip region CHR1 and the first scribe lane region SR1. The second inner boundary IB2 may mean the boundary between the second chip region CHR2 and the second scribe lane region SR2. The first outer boundary OB1 and the second outer boundary OB2 may mean the boundary between the first scribe lane region SR1 and the second scribe lane region SR2. The first outer boundary OB1 and the second outer boundary OB2 may indicate the same boundary.

The first semiconductor device includes first guard rings GR1, first alignment patterns AP1, and a first cutting guide pattern ISP1. The second semiconductor device includes second guard rings GR2, second alignment patterns AP2, and a second cutting guide pattern ISP2.

The first guard rings GR1 may be disposed in the first chip region CHR1. The second guard rings GR2 may be disposed in the second chip region CHR2. In an embodiment, the first guard rings GR1 and the second guard rings GR2 may play the role of protecting various wirings and elements included in the first chip region CHR1 and the second chip region CHR2. In an embodiment, the first guard rings GR1 may be partially disposed also in the first scribe lane region SR1. The second guard rings GR2 may be partially disposed also in the second scribe lane region SR2.

The first alignment patterns AP1 may be disposed in the first scribe lane region SR1. The second alignment patterns AP2 may be disposed in the second scribe lane region SR2. The first alignment patterns AP1 and the second alignment patterns AP2 may be keys that are used to align components included in the first semiconductor device and the second semiconductor device when forming the first semiconductor device and the second semiconductor device. In an embodiment, the first and second alignment patterns AP1 and AP2 may include alignment keys.

The first alignment patterns AP1 may each be disposed to extend in a direction that intersects the first inner boundary IB1. In the present specification, being disposed in a direction intersecting a boundary may mean being disposed so that a width in the direction that intersects the boundary is wider than a width in a direction that is parallel to the boundary. For example, the width of the first alignment patterns AP1 in the direction that intersects the first inner boundary IB1 may be wider than the width of the first alignment patterns AP1 in a direction that is parallel to the first inner boundary IB1. The first alignment patterns AP1 may be disposed spaced apart from each other in a direction in which the first inner boundary IB1 extends.

Similarly, the second alignment patterns AP2 may be disposed in a direction that intersects the second inner boundary IB2. For example, the width of the second alignment patterns AP2 in the direction that intersects the second inner boundary IB2 may be wider than the width of the second alignment patterns AP2 in a direction that is parallel to the second inner boundary IB2. The second alignment patterns AP2 may be disposed spaced apart from each other in a direction in which the second inner boundary IB2 extends.

In an embodiment, the first alignment patterns AP1 may be spaced apart from the first outer boundary OB1. The second alignment patterns AP2 may be spaced apart from the second outer boundary OB2.

In an embodiment like the one illustrated in FIG. 2, each one of the first alignment patterns AP1 may be spaced apart from the first outer boundary OB1 and, also, from the first inner boundary IB1. Likewise each one of the second alignment patterns AP2 may be spaced apart from the second outer boundary OB2 and, also, from the second inner boundary IB2.

The first cutting guide pattern ISP1 may be disposed in the first scribe lane region SR1. The second cutting guide pattern ISP2 may be disposed in the second scribe lane region SR2. In an embodiment, the first cutting guide pattern ISP1 and the second cutting guide pattern ISP2 may play the role of guiding a direction in which a cutting line passes when cutting semiconductor devices. For example, a cutting line may pass through the region between the first cutting guide pattern ISP1 and the second cutting guide pattern ISP2, as a region with relatively low density.

In an embodiment, the first cutting guide pattern ISP1 may be disposed to extend in a direction that intersects the first alignment patterns AP1. For example, the first cutting guide pattern ISP1 may extend in a direction perpendicular or substantially perpendicular to the first alignment patterns AP1. In an embodiment, the second cutting guide pattern ISP2 may be disposed in a direction that intersects the second alignment patterns AP2. For example, the second cutting guide pattern ISP2 may extend in a direction perpendicular or substantially perpendicular to the second alignment patterns AP2.

In an embodiment, a width d1 of the first cutting guide pattern ISP1 in a direction that intersects the first inner boundary IB1 may be narrower than a width d2 of the first cutting guide pattern ISP1 in a direction that intersects the first alignment patterns AP1. In an embodiment like the one illustrated in FIG. 2, a width of the second cutting guide pattern ISP2 in a direction that intersects the second inner boundary IB2 may be narrower than a width of the second cutting guide pattern ISP2 in a direction that intersects the second alignment patterns AP2.

In an embodiment, a width d1 of the first cutting guide pattern ISP1 in a direction that intersects the first inner boundary IB1 may be the same with a width of the second cutting guide pattern ISP2 in a direction that intersects the second inner boundary IB2. In an embodiment, the width of the first cutting guide pattern ISP1 in a direction that intersects the first alignment patterns AP1 may be the same with the width of the second cutting guide pattern ISP2 in a direction that intersects the second alignment patterns AP2.

In an embodiment, the first cutting guide pattern ISP1 may be disposed to overlap with one or more first alignment patterns AP1. The second cutting guide pattern ISP2 may be disposed to overlap with one or more second alignment patterns AP2.

Although FIG. 2 illustrates four first alignment patterns AP1, four second alignment patterns AP2, one first cutting guide pattern ISP1, and one second cutting guide pattern these are only provided for the sake of convenience, and the numbers of first and second alignment patterns AP1 and AP2 and the first and second cutting guide patterns ISP1 and ISP2 are not limited thereto.

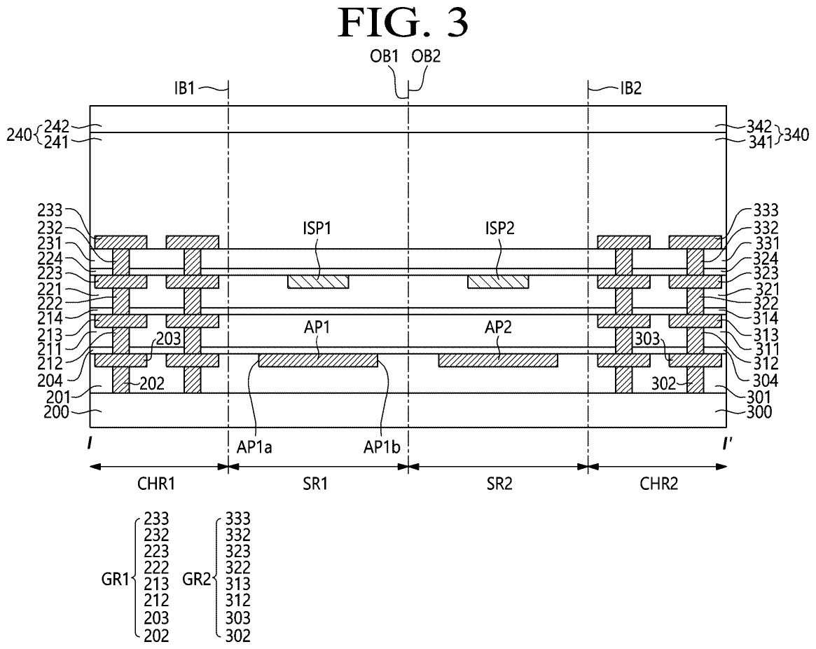

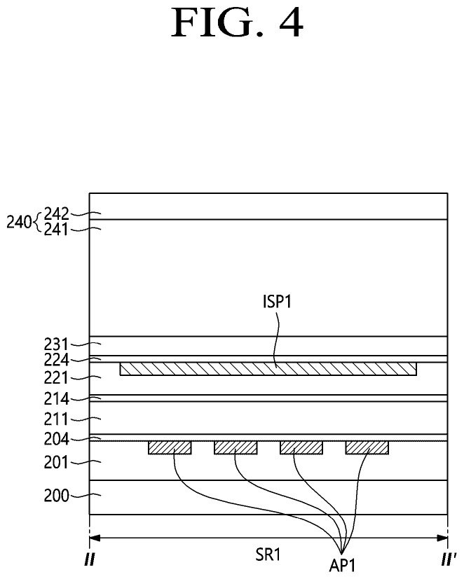

FIG. 3 is a view illustrating a cross-sectional structure of a part indicated by a line I-I′ of FIG. 2. FIG. 4 is a view illustrating a cross-sectional structure of a part indicated by a line II-II′ of FIG. 2.

Referring now to FIG. 3 and FIG. 4, the first semiconductor device may include a first substrate 200, a first insulating layer 201 disposed on the substrate 200, the first guard rings GR1, a first interlayer insulating layer 204, a second insulating layer 211, a second interlayer insulating layer 214, a third insulating layer 221, a third interlayer insulating layer 224, a fourth insulating layer 231, a first passivation layer 240, the first alignment patterns AP1, and the first cutting guide pattern ISP1. For example, each of the first guard rings GR1 may include a first contact 202, a first wiring 203, a second contact 212, a second wiring 213, a third contact 222, a third wiring 223, a fourth contact 232, and a fourth wiring 233. The first passivation layer 240 may include a first lower passivation layer 241 and a first upper passivation layer 242 formed on the first lower passivation layer 241.

Referring to FIG. 2 and FIG. 3, the first substrate 200 may include the first chip region CHR1 and the first scribe lane region SR1. The first substrate 200 may include a semiconductor substrate such as a silicon wafer or a silicon-on-insulator (SOI) wafer. The first substrate 200 may include a III-V group semiconductor substrate, for example, a compound semiconductor substrate such as GaAs. The first substrate 200 may include monocrystalline silicon, polysilicon, amorphous silicon, monocrystalline silicon germanium, polycrystalline silicon germanium, carbon-doped silicon, or a combination thereof.

The first insulating layer 201 and the first contact 202 and the first wiring 203 of the first guard ring GR1 are disposed on the first substrate 200. The first guard ring GR1 may be disposed in the first chip region CHR1. The first insulating layer 201 may include, for example, silicon oxide, silicon nitride, silicon oxynitride, low-k dielectric, high-k dielectric, or a combination thereof. In an embodiment, the first insulating layer 201 may include oxide such as tetraethyl orthosilicate (TEOS). The first contact 202 and the first wiring 203 may include a conductive material such as, for example, metal, metal oxide, metal nitride, metal silicide, polysilicon, conductive carbon or a combination thereof. The first contact 202 and the first wiring 203 may include, for example, tungsten (W), tungsten nitride (WN), titanium (Ti), titanium nitride (TiN), aluminum (Al), copper (Cu), tantalum (Ta), tantalum nitride (TaN), gold (Au), or a combination thereof.

The first alignment patterns AP1 may be disposed in the first insulating layer 201 in the first scribe lane region SR1. In an embodiment, each of the first alignment patterns AP1 may play the role of an alignment key to provide alignment when forming the second contact 212, however, the role of the first alignment patterns AP1 is not necessarily limited thereto. For example, in an embodiment, the first alignment patterns AP1 may be disposed in the second insulating layer 211, and, in this case, the first alignment patterns AP1 may play the role of an alignment key to provide alignment when forming the third contact 222.

Each first alignment patterns AP1 may include a first side surface AP1a that neighbors the first inner boundary IB1 of the first scribe lane region SR1 and a second side surface AP1b that neighbors the first outer boundary OB1 of the first scribe lane region SR1. In an embodiment, as illustrated in FIG. 3, the second side surface AP1b of the first alignment patterns AP1 may be spaced apart from the first outer boundary OB1 of the first scribe lane region SR1. Also, in an embodiment, the first side surface AP1a may be spaced apart from the first inner boundary IB1 of the first scribe lane region SR1.

In an embodiment, the first alignment patterns AP1 may be formed in the same process as the first wiring 203. For example, the first alignment patterns AP1 may include the same material as the first wiring 203.

The first interlayer insulating layer 204 is disposed on the first wiring 203, the first alignment patterns AP1 and the first insulating layer 201 in the first chip region CHR1 and the first scribe lane region SR1. The first interlayer insulating layer 204 may include silicon oxide, silicon nitride, silicon oxynitride, low-k dielectric, high-k dielectric, or a combination thereof. In an embodiment, the first interlayer insulating layer 204 may include silicon nitride.

The second insulating layer 211 is disposed on the first interlayer insulating layer 204. The second contact 212 and the second wiring 213 of the first guard ring GR1 are disposed in the second insulating layer 211. The second contact 212 may be connected to the first wiring 203 by passing through the second insulating layer 211 and the first interlayer insulating layer 204. Each of the second insulating layer 211, the second contact 212 and the second wiring 213 may include the same material as each of the first insulating layer 201, the first contact 202 and the first wiring 203.

The third insulating layer 221 is disposed on the second interlayer insulating layer 214. The third contact 222 and the third wiring 223 of the first guard ring GR1 are disposed in the third insulating layer 221. The third contact 222 may be connected to the second wiring 213 by passing through the third insulating layer 221 and the second interlayer insulating layer 214. Each of the third insulating layer 221, the third contact 222 and the third wiring 223 may include the same material as each of the first insulating layer 201, the first contact 202 and the first wiring 203.

The first cutting guide pattern ISP1 may be disposed in the third insulating layer 221 in the first scribe lane region SR1. In an embodiment, the first cutting guide pattern ISP1 may be located between the first side surface AP1a and the second side surface AP1b of the first alignment patterns AP1. In an embodiment, the first alignment patterns AP1 may be closer to the first outer boundary OB1 of the first scribe lane region SR1 than the first cutting guide pattern ISP1. In the illustrated embodiment of FIG. 3 the width of the first cutting guide pattern ISP1 may be narrower than a width of the first alignment patterns AP1, and the side surface of the first cutting guide pattern ISP1 may be further away than the side surfaces of the first alignment patterns AP1 from the first outer boundary OB1 and the first inner boundary IB1.

The first cutting guide pattern ISP1 may include a conductive material such as metal, metal oxide, metal nitride, metal silicide, polysilicon, conductive carbon or a combination thereof.

The third interlayer insulating layer 224 is disposed on the third wiring 223, the first cutting guide pattern ISP1 and the third insulating layer 221. The third interlayer insulating layer 224 may include the same material as the first interlayer insulating layer 204.

The fourth insulating layer 231 is disposed on the third interlayer insulating layer 224. The fourth contact 232 of the first guard ring GR1 is disposed in the fourth insulating layer 231. The fourth contact 232 may be connected to the third wiring 223 by passing through the fourth insulating layer 231 and the third interlayer insulating layer 224. Each of the fourth insulating layer 231 and the fourth contact 232 may include the same material as each of the first insulating layer 201 and the first contact 202.

The first lower passivation layer 241 is disposed on the fourth wiring 233 and the fourth insulating layer 231. The first lower passivation layer 241 may cover the upper surface and the side surface of the fourth wiring 233. The first lower passivation layer 241 may include silicon oxide, silicon nitride, silicon oxynitride, low-k dielectric, high-k dielectric, or a combination thereof. In an embodiment, the first lower passivation layer 241 may include high density plasma (HDP) oxide.

The first upper passivation layer 242 is disposed on the first lower passivation layer 241. In an embodiment, the first upper passivation layer 242 may include silicon nitride.

The second semiconductor device may include a second substrate 300, a fifth insulating layer 301, the second guard rings GR2, a fourth interlayer insulating layer 304, a sixth insulating layer 311, a fifth interlayer insulating layer 314, a seventh insulating layer 321, a sixth interlayer insulating layer 324, an eighth insulating layer 331, a second passivation layer 340, the second alignment patterns AP2, and the second cutting guide pattern ISP2. Each second guard ring GR2 may include a fifth contact 302, a fifth wiring 303, a sixth contact 312, a sixth wiring 313, a seventh contact 322, a seventh wiring 323, an eighth contact 332, and an eighth wiring 333. The second passivation layer 340 may include a second lower passivation layer 341 and a second upper passivation layer 342 formed on the second lower passivation layer 341. The components included in the second semiconductor device may be substantially the same as the components, respectively, of the first semiconductor device described above with reference to FIG. 2 to FIG. 4.

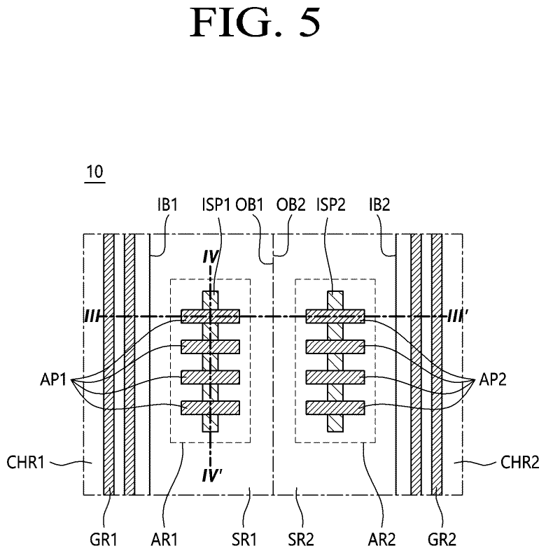

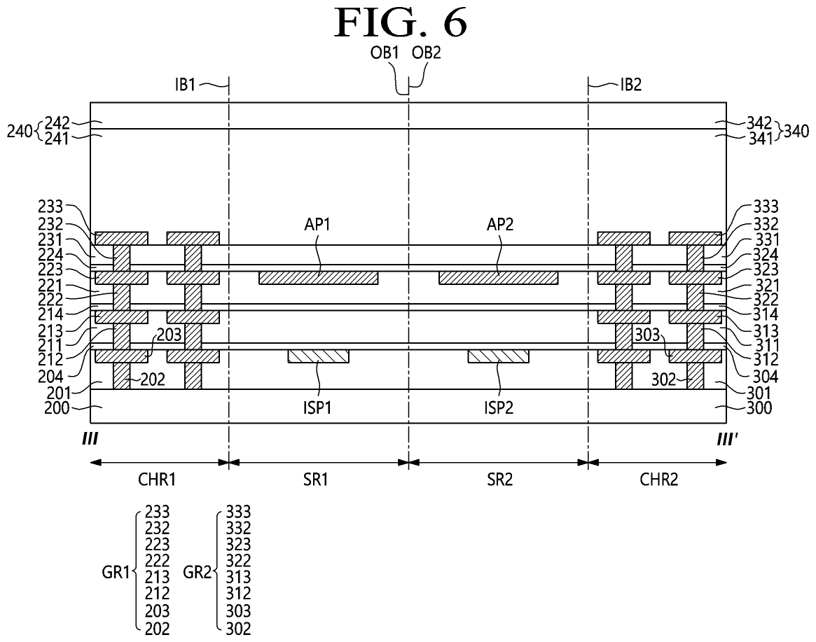

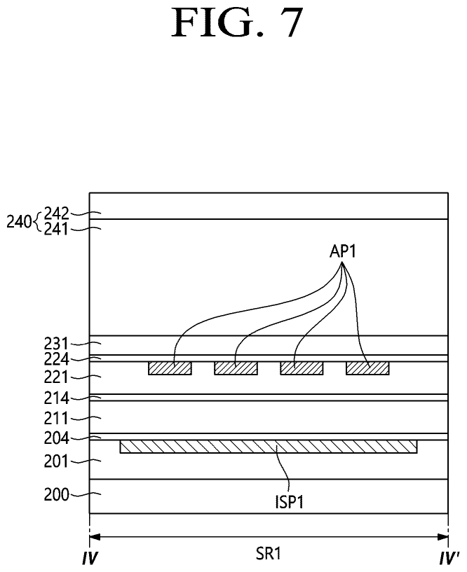

FIG. 5 is an enlarged view illustrating another embodiment of the part 10 of FIG. 1. FIG. 6 is a view illustrating a cross-sectional structure of a part indicated by a line III-III′ of FIG. 5. FIG. 7 is a view illustrating a cross-sectional structure of a part indicated by a line IV-IV′ of FIG. 5.

Referring to FIG. 5 to FIG. 7, the first semiconductor device may include a first substrate 200, a first insulating layer 201 formed on the first substrate 200, first guard rings GR1, a first interlayer insulating layer 204, a second insulating layer 211, a second interlayer insulating layer 214, a third insulating layer 221, a third interlayer insulating layer 224, a fourth insulating layer 231, a first passivation layer 240, first alignment patterns AP1, and a first cutting guide pattern ISP1. Each first guard ring GR1 may include a first contact 202, a first wiring 203, a second contact 212, a second wiring 213, a third contact 222, a third wiring 223, a fourth contact 232, and a fourth wiring 233. The first passivation layer 240 may include a first lower passivation layer 241 and a first upper passivation layer 242 formed on the first lower passivation layer 241.

The first cutting guide pattern ISP1 is located below the first alignment patterns AP1. The first cutting guide pattern ISP1 is disposed between the first alignment patterns AP1 and the first substrate 200. In the illustrated embodiment of FIG. 6, the first cutting guide pattern ISP1 is disposed in the first insulating layer 201 in the first scribe lane region SR1. However, the embodiments are not limited thereto, and the first cutting guide pattern ISP1 may be disposed at any location between the first alignment patterns AP1 and the first substrate 200. For example, in another embodiment, the first cutting guide pattern ISP1 may be disposed in the second insulating layer 211.

In an embodiment, the first cutting guide pattern ISP1 may be disposed to overlap with one or more first alignment patterns AP1. Although FIG. 5 illustrates four first alignment patterns AP1 and one first cutting guide pattern ISP1, this is for the sake of convenience, and the numbers of first alignment patterns AP1 and first cutting guide patterns ISP1 are not limited thereto.

As illustrated in FIG. 5, the first cutting guide pattern ISP1 may be located farther away from a first outer boundary OB1 of the first scribe lane region SR1 than the first alignment patterns AP1.

The first alignment patterns AP1 may be disposed in the third insulating layer 221 in the first scribe lane region SR1. The first alignment patterns AP1 may be disposed to overlap with the first cutting guide pattern ISP1. The first alignment patterns AP1 may be spaced apart from the first outer boundary OB1 of the first scribe lane region SR1. In an embodiment, the first alignment patterns AP1 may be spaced apart also from the first inner boundary IB1 of the first scribe lane region SR1.

The second semiconductor device may include a second substrate 300, a fifth insulating layer 301, second guard rings GR2, a fourth interlayer insulating layer 304, a sixth insulating layer 311, a fifth interlayer insulating layer 314, a seventh insulating layer 321, a sixth interlayer insulating layer 324, an eighth insulating layer 331, a second passivation layer 340, second alignment patterns AP2, and a second cutting guide pattern ISP2. Each second guard ring GR2 may include a fifth contact 302, a fifth wiring 303, a sixth contact 312, a sixth wiring 313, a seventh contact 322, a seventh wiring 323, an eighth contact 332, and an eighth wiring 333. The second passivation layer 340 may include a second lower passivation layer 341 and a second upper passivation layer 342 formed on the second lower passivation layer 341. The components included in the second semiconductor device may be substantially the same as the components, respectively, of the first semiconductor device described above with reference to FIG. 5 to FIG. 7.

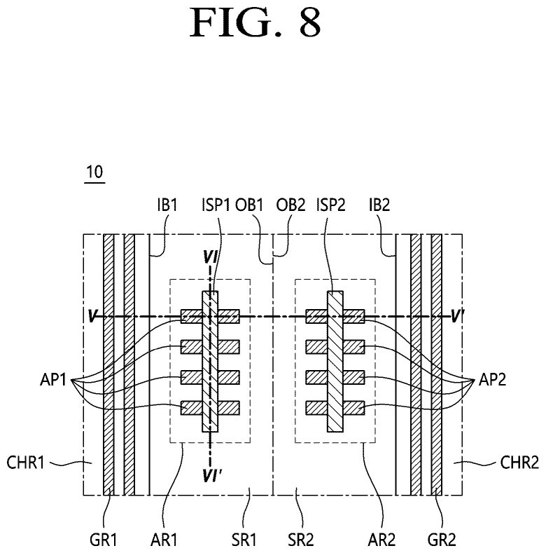

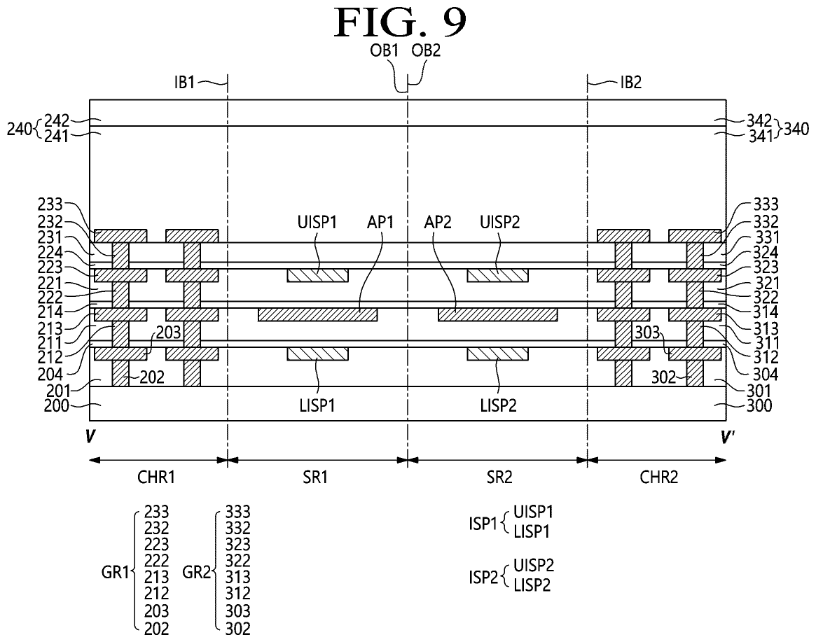

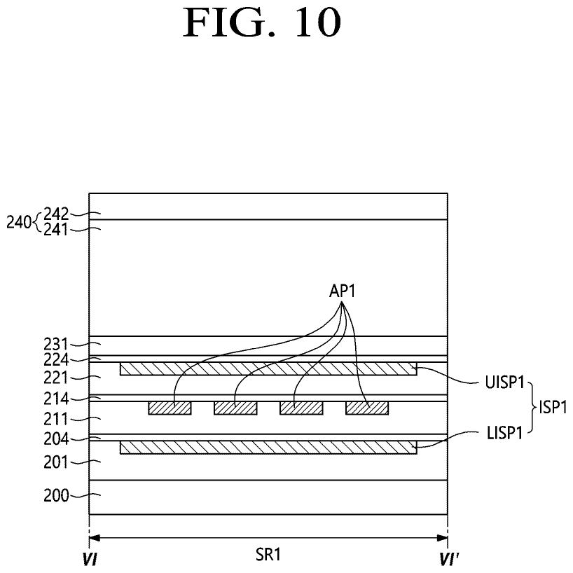

FIG. 8 is an enlarged view illustrating another embodiment of the part 10 of FIG. 1. FIG. 9 is a view illustrating a cross-sectional structure of a part indicated by a line V-V′ of FIG. 8. FIG. 10 is a view illustrating a cross-sectional structure of a part indicated by a line VI-VI′ of FIG. 8.

Referring to FIG. 8 to FIG. 10, the first semiconductor device may include a first substrate 200, a first insulating layer 201, first guard rings GR1, a first interlayer insulating layer 204, a second insulating layer 211, a second interlayer insulating layer 214, a third insulating layer 221, a third interlayer insulating layer 224, a fourth insulating layer 231, a first passivation layer 240, first alignment patterns AP1, and a first cutting guide pattern ISP1. Each first guard ring GR1 may include a first contact 202, a first wiring 203, a second contact 212, a second wiring 213, a third contact 222, a third wiring 223, a fourth contact 232, and a fourth wiring 233. The first passivation layer 240 may include a first lower passivation layer 241 and a first upper passivation layer 242.

The first cutting guide pattern ISP1 is disposed in the first scribe lane region SR1, and includes a first upper cutting guide pattern UISP1 and a first lower cutting guide pattern LISP1. The first upper cutting guide pattern UISP1 and the first lower cutting guide pattern LISP1 may be disposed spaced apart from each other.

The first lower cutting guide pattern LISP1 is located below the first alignment patterns AP1. The first lower cutting guide pattern LISP1 may be disposed between the first alignment patterns AP1 and the first substrate 200. In an embodiment, the first lower cutting guide pattern LISP1 may be disposed in the first insulating layer 201. However, the embodiments are not limited thereto, and the first lower cutting guide pattern LISP1 may be disposed at any location between the first alignment patterns AP1 and the first substrate 200.

The first upper cutting guide pattern UISP1 is located over the first alignment patterns AP1. In an embodiment, the first upper cutting guide pattern UISP1 may be disposed in the third insulating layer 221. However, the embodiments are not limited thereto, and the first upper cutting guide pattern UISP1 may be disposed at any location over the first alignment patterns AP1.

In an embodiment, the first cutting guide pattern ISP1 may be disposed to overlap with one or more first alignment patterns AP1. Although FIG. 8 illustrates four first alignment patterns AP1 and one first cutting guide pattern ISP1, this is for the sake of convenience, and the numbers of first alignment patterns AP1 and first cutting guide patterns ISP1 are not limited thereto.

In an embodiment, the first cutting guide pattern ISP1 may be located farther away from a first outer boundary OB1 of the first scribe lane region SR1 than the first alignment patterns AP1.

The first alignment patterns AP1 may be disposed in the second insulating layer 211 in the first scribe lane region SR1. The first alignment patterns AP1 may be disposed to overlap with the first upper cutting guide pattern UISP1 and the first lower cutting guide pattern LISP1. In an embodiment, the first alignment patterns AP1 may be spaced apart from the first outer boundary OB1 of the first scribe lane region SR1.

The second semiconductor device may include a second substrate 300, a fifth insulating layer 301, second guard rings GR2, a fourth interlayer insulating layer 304, a sixth insulating layer 311, a fifth interlayer insulating layer 314, a seventh insulating layer 321, a sixth interlayer insulating layer 324, an eighth insulating layer 331, a second passivation layer 340, second alignment patterns AP2, and a second cutting guide pattern ISP2. Each second guard ring GR2 may include a fifth contact 302, a fifth wiring 303, a sixth contact 312, a sixth wiring 313, a seventh contact 322, a seventh wiring 323, an eighth contact 332, and an eighth wiring 333. The second passivation layer 340 may include a second lower passivation layer 341 and a second upper passivation layer 342 formed on the second lower passivation layer 341. The second cutting guide pattern ISP2 may include a second upper cutting guide pattern UISP2 and a second lower cutting guide pattern LISP2. The components included in the second semiconductor device may be substantially the same as the components, respectively, of the first semiconductor device described above with reference to FIG. 8 to FIG. 10.

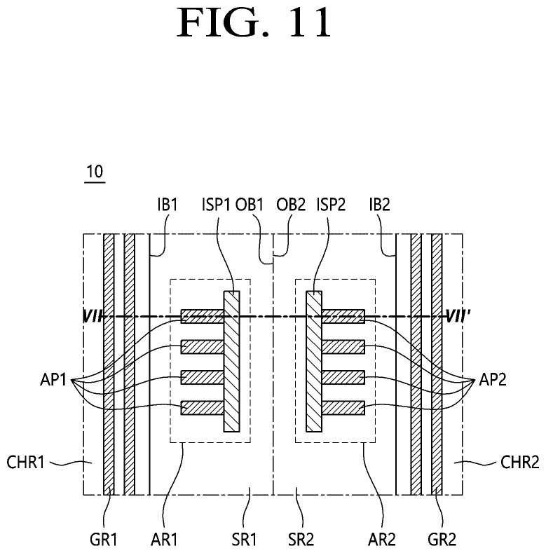

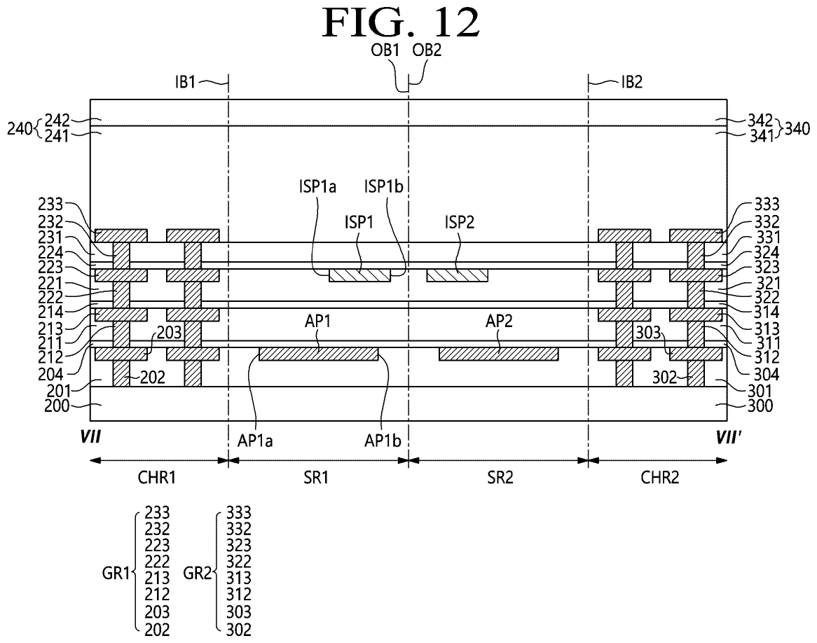

FIG. 11 is an enlarged view illustrating another embodiment of the part 10 of FIG. 1. FIG. 12 is a view illustrating a cross-sectional structure of a part indicated by a line VII-VII′ of FIG. 11.

Referring to FIG. 11 and FIG. 12, the first semiconductor device may include a first substrate 200, a first insulating layer 201, first guard rings GR1, a first interlayer insulating layer 204, a second insulating layer 211, a second interlayer insulating layer 214, a third insulating layer 221, a third interlayer insulating layer 224, a fourth insulating layer 231, a first passivation layer 240, first alignment patterns AP1, and a first cutting guide pattern ISP1. Each first guard ring GR1 may include a first contact 202, a first wiring 203, a second contact 212, a second wiring 213, a third contact 222, a third wiring 223, a fourth contact 232, and a fourth wiring 233. The first passivation layer 240 may include a first lower passivation layer 241 and a first upper passivation layer 242 formed on the first lower passivation layer 241.

The first alignment patterns AP1 may be disposed in the first insulating layer 201 in the first scribe lane region SR1. At least a part of the first alignment patterns AP1 may overlap with the first cutting guide patterns ISP1. Each of the first alignment patterns AP1 includes a first side surface AP1a that neighbors a first inner boundary IB1 and a second side surface AP1b that neighbors a first outer boundary OB1. In an embodiment, the second side surface AP1b of the first alignment patterns AP1 may be spaced apart from the first outer boundary OB1 of the first scribe lane region SR1.

The first cutting guide pattern ISP1 may be disposed in the third insulating layer 221 in the first scribe lane region SR1. The first cutting guide pattern ISP1 includes a first side surface ISP1a that neighbors the first inner boundary IB1 and a second side surface ISP1b that neighbors the first outer boundary OB1. In an embodiment, the first cutting guide pattern ISP1 may be located closer to the first outer boundary OB1 than the first alignment patterns AP1. For example, the second side surface ISP1b of the first cutting guide pattern ISP1 may be located closer to the first outer boundary OB1 than the second side surface AP1b of the first alignment patterns AP1. For example, the second side surface ISP1b of the first cutting guide pattern ISP1 may be located between the second side surface AP1b of the first alignment patterns AP1 and the first outer boundary OB1. In an embodiment, when performing a cutting process of a semiconductor device, cutting may occur along the region between the second side surface ISP1b of the first cutting guide pattern ISP1 and the first outer boundary OB1. Because the first cutting guide pattern ISP1 is disposed closer to the first outer boundary OB1 than the first alignment patterns AP1, the straightness of a cutting progression direction may be further secured, and thus, a cutting defect may be prevented more effectively.

The second semiconductor device may include a second substrate 300, a fifth insulating layer 301, second guard rings GR2, a fourth interlayer insulating layer 304, a sixth insulating layer 311, a fifth interlayer insulating layer 314, a seventh insulating layer 321, a sixth interlayer insulating layer 324, an eighth insulating layer 331, a second passivation layer 340, second alignment patterns AP2, and a second cutting guide pattern ISP2. Each second guard ring GR2 may include a fifth contact 302, a fifth wiring 303, a sixth contact 312, a sixth wiring 313, a seventh contact 322, a seventh wiring 323, an eighth contact 332, and an eighth wiring 333. The second passivation layer 340 may include a second lower passivation layer 341 and a second upper passivation layer 342 formed on the second lower passivation layer 341. The components included in the second semiconductor device may be substantially the same as the components, respectively, of the first semiconductor device described above with reference to FIG. 11 and FIG. 2.

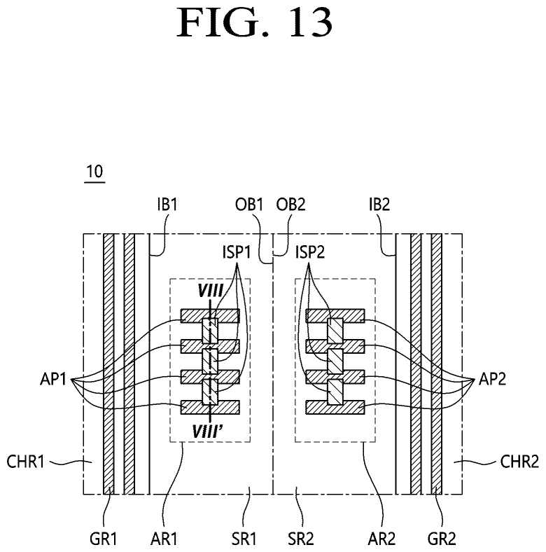

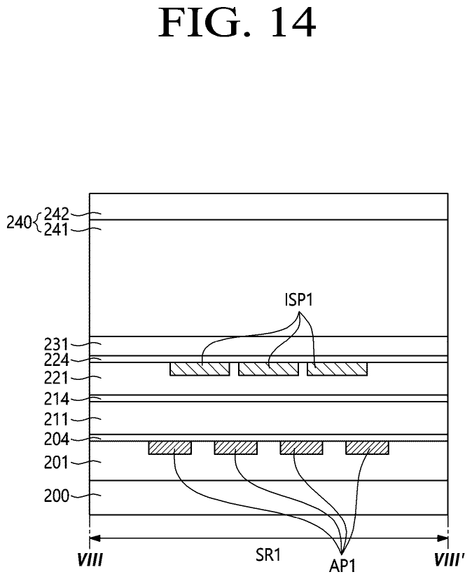

FIG. 13 is an enlarged view illustrating another embodiment of the part 10 of FIG. 1. FIG. 14 is a view illustrating a cross-sectional structure of a part indicated by a line VIII-VIII′ of FIG. 13.

Referring to FIG. 13 and FIG. 14, the first semiconductor device may include a first substrate 200, a first insulating layer 201, first guard rings GR1, a first interlayer insulating layer 204, a second insulating layer 211, a second interlayer insulating layer 214, a third insulating layer 221, a third interlayer insulating layer 224, a fourth insulating layer 231, a first passivation layer 240, first alignment patterns AP1, and first cutting guide patterns ISP1. Each first guard ring GR1 may include a first contact 202, a first wiring 203, a second contact 212, a second wiring 213, a third contact 222, a third wiring 223, a fourth contact 232, and a fourth wiring 233. The first passivation layer 240 may include a first lower passivation layer 241 and a first upper passivation layer 242 formed on the first lower passivation layer 241.

The first alignment patterns AP1 may be disposed in the first insulating layer 201 in the first scribe lane region SR1. At least some of the first alignment patterns AP1 may overlap with the first cutting guide patterns ISP1. The first alignment patterns AP1 may be spaced apart from each other in a direction parallel to the first inner boundary IB1 or the first outer boundary OB1. The first insulating layer 201 may be located in the spaces between the first alignment patterns AP1 that are spaced apart from each other.

The first cutting guide patterns ISP1 may be disposed in the third insulating layer 221 in the first scribe lane region SR1. The first cutting guide pattern ISP1 may be spaced apart from each other in a direction that intersects a direction in which the first alignment patterns AP1 are disposed. The spaced-apart first cutting guide patterns ISP1 may be arranged in the direction that intersects the direction in which the first alignment patterns AP1 are disposed. In an embodiment, the first cutting guide patterns ISP1 may correspond to sections, respectively, of the first insulating layer 201 that are located between the spaced-apart first alignment patterns AP1. For example, the section of the first insulating layer 201 located between the first alignment patterns AP1 may overlap with the first cutting guide pattern ISP1.

The second semiconductor device may include a second substrate 300, a fifth insulating layer 301, second guard rings GR2, a fourth interlayer insulating layer 304, a sixth insulating layer 311, a fifth interlayer insulating layer 314, a seventh insulating layer 321, a sixth interlayer insulating layer 324, an eighth insulating layer 331, a second passivation layer 340, second alignment patterns AP2, and second cutting guide patterns ISP2. Each second guard ring GR2 may include a fifth contact 302, a fifth wiring 303, a sixth contact 312, a sixth wiring 313, a seventh contact 322, a seventh wiring 323, an eighth contact 332, and an eighth wiring 333. The second passivation layer 340 may include a second lower passivation layer 341 and a second upper passivation layer 342 formed on the second lower passivation layer 341. The components included in the second semiconductor device may be substantially the same as the components, respectively, of the first semiconductor device described above with reference to FIG. 13 and FIG. 14.

Referring again to FIG. 2, the first alignment patterns AP1 are disposed spaced apart from the first outer boundary OB1 of the first scribe lane region SR1. The first cutting guide patterns ISP1 overlap with the first alignment patterns AP1, and are disposed in a direction that intersects the first alignment patterns AP1.

According to embodiments of the present disclosure, because the first alignment patterns AP1 are disposed spaced apart from the first outer boundary OB1 of the first scribe lane region SR1, a cutting line may pass between the first outer boundary OB1 and the first alignment patterns AP1 during a cutting process. The straightness of cutting may increase, so that a cutting defect likely to occur due to cutting in an undesired direction may be minimized.

In addition, the first cutting guide patterns ISP1 may extend in substantially the same direction as a cutting line. Therefore, during a cutting process, it is possible to prevent a cutting line from deviating from the first scribe lane region SR1 to propagate to the first chip region CHR1. Furthermore, because a cutting line may be guided to pass through the region between cutting guide patterns, the straightness of cutting may increase. Thus, cutting defects may be minimized.

Moreover, because the first cutting guide patterns ISP1 may play the role of absorbing stress generated in a direction in which a cutting line passes during a cutting process, a delamination or a crack that may occur between respective layers included in a semiconductor device during a cutting process may be minimized.

While the detailed embodiments of the present disclosure are disclosed, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope. Furthermore, the embodiments may be combined to form additional embodiments.

What is claimed is:

1. A semiconductor device comprising:
a substrate including a chip region and a scribe lane region disposed around the chip region, the scribe lane region including an inner boundary that abuts the chip region and an outer boundary that is spaced apart from the inner boundary;
alignment patterns disposed in the scribe lane region on the substrate, spaced apart from each other in a direction in which the outer boundary extends, and disposed spaced apart from the outer boundary; and
cutting guide patterns located in the scribe lane region on the substrate, overlapping with at least some of the alignment patterns, and disposed in a direction that intersects the alignment patterns.

2. The semiconductor device according to claim 1, wherein the cutting guide patterns are disposed over the alignment patterns.

3. The semiconductor device according to claim 1, wherein the cutting guide patterns are disposed between the substrate and the alignment patterns.

4. The semiconductor device according to claim 1, wherein:
the cutting guide patterns include upper cutting guide patterns and lower cutting guide patterns, and
the alignment patterns are disposed between the upper cutting guide patterns and the lower cutting guide patterns.

5. The semiconductor device according to claim 1, wherein:
each of the alignment patterns includes one side surface that neighbors the inner boundary and one other side surface opposite to the one side surface that neighbors the outer boundary, and
the cutting guide patterns are disposed between the one side surface and the other side surface.

6. The semiconductor device according to claim 5, wherein the one other side surface of each of the alignment patterns is spaced apart from the outer boundary.

7. The semiconductor device according to claim 1, wherein the cutting guide patterns are disposed closer to the outer boundary than the alignment patterns.

8. The semiconductor device according to claim 1, wherein the cutting guide patterns are spaced apart from each other in a direction that intersects the alignment patterns.

9. The semiconductor device according to claim 8, wherein the cutting guide patterns are disposed to correspond to regions, respectively, disposed between the spaced-apart alignment patterns.

10. The semiconductor device according to claim 1, wherein a width of the cutting guide patterns in a direction that intersects the alignment patterns is wider than a width of the cutting guide patterns in a direction that intersects the inner boundary.

11. A semiconductor device comprising:
a substrate including a chip region and a scribe lane region disposed around the chip region;
alignment patterns disposed in the scribe lane region on the substrate, and spaced apart from each other in a direction in which a boundary between the chip region and the scribe lane region extends; and
cutting guide patterns disposed in the scribe lane region on the substrate, overlapping with at least some of the alignment patterns, and having a width in a direction that intersects the alignment patterns wider than a width in a direction that intersects the boundary between the chip region and the scribe lane region.

12. The semiconductor device according to claim 11, wherein the cutting guide patterns are disposed over the alignment patterns.

13. The semiconductor device according to claim 11, wherein the cutting guide patterns are disposed between the substrate and the alignment patterns.

14. The semiconductor device according to claim 11, wherein:
the cutting guide patterns include upper cutting guide patterns and lower cutting guide patterns, and
the alignment patterns are disposed between the upper cutting guide patterns and the lower cutting guide patterns.

15. The semiconductor device according to claim 11, wherein the cutting guide patterns are disposed in a direction that intersects the alignment patterns.

16. The semiconductor device according to claim 11, wherein:
the scribe lane region includes an inner boundary that abuts the chip region and an outer boundary that is spaced apart from the inner boundary, and
the alignment patterns are spaced apart from the outer boundary.

17. The semiconductor device according to claim 16, wherein:
each of the alignment patterns includes one side surface that neighbors the inner boundary and one other side surface opposite the one side surface that neighbors the outer boundary, and
the cutting guide patterns are disposed between the one side surface and the one other side surface.

18. The semiconductor device according to claim 16, wherein the cutting guide patterns are disposed closer to the outer boundary than the alignment patterns.

19. The semiconductor device according to claim 11, wherein the cutting guide patterns are spaced apart from each other in a direction that intersects the alignment patterns.

20. The semiconductor device according to claim 19, wherein the cutting guide patterns are disposed to correspond to regions between the spaced-apart alignment patterns.
